(19) United States
(12) Patent Application Publication
(10) Pub. No.: US 2026/0305171 A1
(43) Pub. Date: Oct. 1, 2026

(54) THERMOELECTRIC MODULES WITH ENHANCED HEAT-TRANSFER AND POWER DENSITY

(71) Applicant: UNIVERSITY OF SOUTH CAROLINA, COLUMBIA, SC (US)

(72) Inventors: HOSSEIN HAJ-HARIRI, COLUMBIA, SC (US); REZA MONAZAMI, IRVINE, CA (US); SAHAR JAHANI, ATLANTA, GA (US)

(21) Appl. No.: 19/095,369

(22) Filed: Mar. 31, 2025

(51) Int. Cl. H10N 19/00; H10N 10/01

(52) U.S. Cl. CPC H10N 19/101; H10N 10/01

(57) ABSTRACT

Devices and related methodology provide improved thermoelectric modules with enhanced features and performance attributes. Thermoelectric modules include thermoelectric elements sandwiched between two electrically insulating ceramic plates, and thermal energy flows from one ceramic plate to the other depending on the direction of an associated electric current. Presently disclosed designs in some instances address broad cases where thermoelectric modules are employed to control temperature and manage thermal loads in conjunction with one or more fluid loops operating between the device and a heat source or cold reservoir. Thermoelectric modules include thermoelectric elements sandwiched between two electrically insulating ceramic plates, with thermal energy flowing from one ceramic plate to the other depending on the direction of associated electric current. Presently disclosed configurations boost thermal performance of thermoelectric systems by eliminating additional layers and integrating fluidic grooves directly into the ceramic, for denser distribution of thermoelectric elements and better performance.

### BACKGROUND OF THE PRESENTLY DISCLOSED SUBJECT MATTER

The presently disclosed subject matter deals with devices and associated and/or related methodology for providing improved thermoelectric modules with enhanced features and performance attributes.

Thermoelectric modules are widely used for temperature control, thermal management, and energy conversion applications. Their ability to precisely control associated temperature and heat flow conditions makes them a top choice in many circumstances. For applications where mobility and reliability are the top priorities, the thermoelectric system's compact form factor and durability makes it a frequently preferred choice.

Generally, thermoelectric modules include thermoelectric elements sandwiched between two electrically insulating ceramic plates. Thermal energy flows from one ceramic plate to the other depending on the direction of an associated electric current, with the lower temperature plate called the cold plate and the higher temperature plate called the hot plate. Advanced designs include additional plates with built-in heat dissipation structures, which add resistance to the heat transfer path. The efficiency of a thermoelectric system in cooling mode is affected by the temperature difference between its hot and cold sides, which is influenced by power input and heat transfer resistance.

Despite their major benefits and advantages in certain respects, the relatively low energy efficiency of thermoelectric systems compared to other heat transfer mechanisms, specifically compression refrigeration systems, typically makes their application limited to a narrow range of use cases.

### SUMMARY OF THE PRESENTLY DISCLOSED SUBJECT MATTER

The presently disclosed apparatus and corresponding and/or associated methodology subject matter generally relates to providing improved thermoelectric modules with enhanced features and performance attributes. More particularly, for some instances, the presently disclosed subject matter achieves a significant boost in performance and efficiency of the underlying thermoelectric modules.

Some exemplary embodiments disclosed herewith relate to new designs and configurations of thermoelectric modules aimed to boost the thermal performance of thermoelectric systems when they are used in applications where at least one of mobility, energy efficiency, form factor, and/or weight are priorities.

Presently disclosed devices and related methodology provide improved thermoelectric modules with enhanced features and performance attributes. Generally, thermoelectric modules include thermoelectric elements sandwiched between two electrically insulating ceramic plates, and thermal energy flows from one ceramic plate to the other depending on the direction of an associated electric current.

Other present exemplary embodiments disclosed herewith in pertinent part address the broad cases where the thermoelectric modules control the associated temperature and manage the associated thermal loads in conjunction with one or two fluid loops operating between the device and the heat source or the cold reservoir.

Presently disclosed subject matter improves efficiency for thermoelectric modules by eliminating additional layers and integrating fluidic grooves directly into the ceramic, allowing for a denser distribution of thermoelectric elements and better performance.

Thermoelectric modules include thermoelectric elements sandwiched between two electrically insulating ceramic plates, with thermal energy flowing from one ceramic plate to the other depending on the direction of associated electric current. Presently disclosed configurations boost thermal performance of thermoelectric systems by eliminating additional layers and integrating fluidic grooves directly into the ceramic, for denser distribution of thermoelectric elements and better performance.

Some presently disclosed embodiments seek enhancement of heat-transfer performance and power density of thermoelectric modules through integration of micro passages in the ceramic faces of the module.

Potential applications of the presently disclosed technology could include a variety of setting, including for example, but without limitation, ice cooling, and such as where people or pets or working animals need to be kept cool from overheating over long periods of time using batteries. Any application where precise temperature control is needed for biological or other similar samples, for long periods of time using batteries is another possible use do exemplary presently disclosed subject matter.

Without limitation, the presently disclosed subject matter relates to mechanical improvements generally and in some instances relating to technology involving thermoelectric modules, ceramic faces, integrated grooves, fluidic chambers, and fluid cooling. Many applications could, for example, be related to defense such as war fighters, canines, tarmac workers, logistics workers, pilots, drivers, or other heat struck personnel, such as airlines: tarmac workers, logistics workers, and mechanics. Various applications may be otherwise applicable, for example, such as involving competitive and recreational athletes.

In some exemplary embodiments disclosed herewith, devices and methods for improved thermoelectric modules are described. One exemplary embodiment presently disclosed relates to a thermoelectric module for transferring heat from one side to the other, using Peltier effect, to provide for both cooling and heating. Such module preferably comprises a pair of ceramic plates, with each plate forming a respective plurality of fluid passages, and with such plates formed in opposing parallel positions; and a plurality of thermoelectric (TE) elements directly captured between such pair of ceramic plates.

Another exemplary embodiment presently disclosed relates to a thermoelectric cooler (TEC) module for transferring heat from one side to the other, using Peltier effect, to controllably create temperature difference between two sides of the module. Such module preferably comprises a pair of dielectric material contact substrates, with such contact substrates formed in opposing parallel positions, and with each contact substrate having a respectively outward facing surface; a respective plurality of fluid passages formed in each of such outward facing surfaces, and comprising at least one of custom-patterned grooves, pins, and other geometries integrated into such outward facing surfaces; and a plurality of thermoelectric (TE) legs, arranged in parallel, and directly captured between such pair of contact substrates.

It is to be understood that the presently disclosed subject matter equally relates to associated and/or corresponding methodologies. One exemplary such method relates to methodology for providing an improved thermoelectric module for transferring heat from one side to the other, using Peltier effect, to provide for both cooling and heating. Such methodology preferably comprises providing a pair of ceramic plates, configured in opposing parallel positions with each plate forming a respective outward facing surfaces; forming a plurality of fluid passages directly in each respective outward facing surface of said ceramic plates; and providing a plurality of thermoelectric (TE) elements directly captured between said pair of ceramic plates, to configure the TE elements for being relatively closer to the plurality of fluid passages, whereby the module has reduced thermal resistance for enhanced performance.

Additional objects and advantages of the presently disclosed subject matter are set forth in, or will be apparent to, those of ordinary skill in the art from the detailed description herein. Also, it should be further appreciated that modifications and variations to the specifically illustrated, referred and discussed features, elements, and steps hereof may be practiced in various embodiments, uses, and practices of the presently disclosed subject matter without departing from the spirit and scope of the subject matter. Variations may include, but are not limited to, substitution of equivalent means, features, or steps for those illustrated, referenced, or discussed, and the functional, operational, or positional reversal of various parts, features, steps, or the like.

Still further, it is to be understood that different embodiments, as well as different presently preferred embodiments, of the presently disclosed subject matter may include various combinations or configurations of presently disclosed features, steps, or elements, or their equivalents (including combinations of features, parts, or steps or configurations thereof not expressly shown in the figures or stated in the detailed description of such figures). Additional embodiments of the presently disclosed subject matter, not necessarily expressed in the summarized section, may include and incorporate various combinations of aspects of features, components, or steps referenced in the summarized objects above, and/or other features, components, or steps as otherwise discussed in this application. Those of ordinary skill in the art will better appreciate the features and aspects of such embodiments, and others, upon review of the remainder of the specification, and will appreciate that the presently disclosed subject matter applies equally to corresponding methodologies as associated with practice of any of the present exemplary devices, and vice versa.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE FIGURES

A full and enabling disclosure of the present subject matter, including the best mode thereof to one of ordinary skill in the art, is set forth more particularly in the remainder of the specification, including reference to the accompanying figures in which:

FIG. 1(A) schematically represents a conventional TEC (Thermoelectric Cooler) module;

FIG. 1(B) schematically represents a TEC (Thermoelectric Cooler) module provided in accordance with presently disclosed subject matter;

FIG. 2(A) illustrates a top view of the thermoelectric elements of the conventional TEC arrangement of FIG. 1(A);

FIG. 2(B) illustrates a top view of the thermoelectric elements of the presently disclosed TEC arrangement of FIG. 1(B);

FIG. 3(A) schematically represents another exemplary embodiment of a conventional TEC (Thermoelectric Cooler) module;

FIG. 3(B) schematically represents another exemplary embodiment of a TEC (Thermoelectric Cooler) module provided in accordance with presently disclosed subject matter; and

FIG. 4 graphically illustrates a dropping maximum Coefficient of Performance (COP) as temperature difference between hot and cold side of the thermoelectric module increases.

Repeat use of reference characters in the present specification and drawings is intended to represent the same or analogous features, elements, or steps of the presently disclosed subject matter.

### DETAILED DESCRIPTION OF THE PRESENTLY DISCLOSED SUBJECT MATTER

Reference will now be made in detail to various embodiments of the disclosed subject matter, one or more examples of which are set forth below. Each embodiment is provided by way of explanation of the subject matter, not limitation thereof. In fact, it will be apparent to those skilled in the art that various modifications and variations may be made in the present disclosure without departing from the scope or spirit of the subject matter. For instance, features illustrated or described as part of one embodiment, may be used in another embodiment to yield a still further embodiment.

As used herein, the term “or” is inclusive unless stated otherwise. For instance, if a computer requires A or B to be true in order to perform operation C, the case of both A and B being true will satisfy the condition necessary for C to occur. That is, “or” is inclusive of A, B, and A and B.

In general, the presently disclosed apparatus and corresponding and/or associated methodology subject matter relates to providing improved thermoelectric modules with enhanced features and performance attributes.

More particularly, the disclosed subject matter achieves significant boost in performance and efficiency of underlying thermoelectric modules through one or more of the following disclosed ideas.

For example, fluid passages in the form of custom-designed and custom-patterned grooves, pins, and other geometries integrated into the ceramic faces of the thermoelectric modules significantly improve the rate of heat transfer from the module through two mechanisms: 1) removing solid material from the ceramic layer, and 2) bringing working fluid in closer contact to the thermoelectric elements in the module. In some embodiments, the fluid passage enclosures use the same ceramic material to reduce thermal stress and tension. The resulting reduction in thermal resistance yields a smaller temperature difference between the hot and cold sides of the thermoelectric module, thereby significantly enhancing the system's overall performance.

For further example, optimized spatial distribution of thermoelectric elements enhances the heat flow and reduces the temperature gradient needed between the cold and hot side of the thermoelectric module. The optimization of the spatial distribution of thermoelectric elements reduces the ohmic resistance of the thermoelectric module by increasing the density of thermoelectric elements per unit area, enabled by the enhanced heat removal capacity.

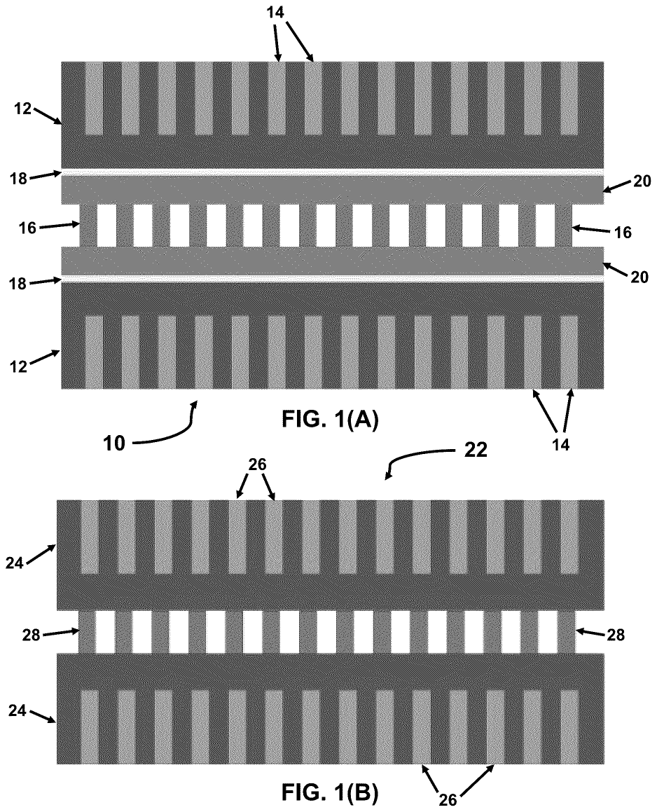

FIG. 1(A) schematically represents a conventional TEC (Thermoelectric Cooler) module generally 10. A TEC (Thermoelectric Cooler) module, or Peltier module, is a type of solid-state or semiconductor device that actively transfers heat from one side to the other, using a so-called Peltier effect, to provide both for cooling and heating. When a current is passed through module 10, a current flows through a junction between two different metals. Whether heat is absorbed or released depends on the direction of the current. Operated accordingly, TEC modules create a temperature difference between the two sides of the module.

Per FIG. 1(A), conventional TEC module 10 is provided with contact plates 12 which have a respective plurality of fluid passages 14. Fluid passages 14 generally allow for thermal management, to improve heat transfer to contribute to a stable temperature differential across the plurality of respective thermoelectric (TE) elements 16. As shown, module 10 is composed of alternating p-type and n-type thermoelectric elements 16, which are arranged in a structured manner between the two ceramic substrates 12.

To complete the overall structure of the exemplary embodiment of representative conventional module 10, a pair of layers of thermal interface material 18 appear respectively sandwiched between substrates 12 and a pair of ceramic plates 20, as shown in FIG. 1(A).

FIG. 1(B) schematically represents a TEC (Thermoelectric Cooler) module generally 22 provided in accordance with presently disclosed subject matter. As shown, such module 22 provides an enhanced thermal performance TEC configuration in accordance with the presently disclosed subject matter, with reduced thermal resistance layers. In particular, for example, the pair of layers of thermal interface material 18 and pair of ceramic plates 20 of FIG. 1(A) are entirely omitted, so that a pair of TE ceramic contact plates 24, each with a respective plurality of fluid passages 26, directly capture the plurality of TE elements 28.

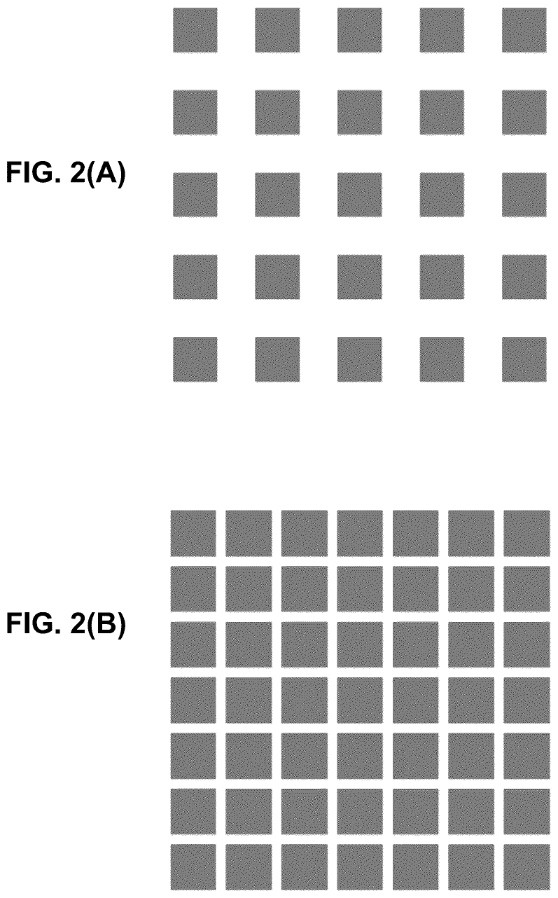

FIG. 2(A) illustrates a top view of the thermoelectric elements of the conventional TEC arrangement of FIG. 1(A), while FIG. 2(B) illustrates a top view of the thermoelectric elements of the presently disclosed TEC arrangement of FIG. 1(B). A comparison of such top views visually represent the enhanced TEC performance and power output per unit area/volume in the configuration of presently disclosed FIG. 1(B) versus the comparatively more sparse arrangement of the conventional construction of FIG. 1(A).

At depicted in FIG. 2(A) and 2(B), the more compact element density in the presently disclosed configuration of FIG. 2(B) delivers twice more power per unit area/volume at higher performance/efficiency than that of the conventional configuration of FIG. 1(A). Such enhancement is mainly enabled by sufficient heat dissipation capacity on each face of the TEC module 22 which prevents temperatures spikes which otherwise would have resulted from increased heat flux and the reduced Ohmic total resistance of the shorter connectors connecting TEC elements (legs) 16 of the FIG. 1(A) conventional configuration. The increased power density and energy efficiency are extremely valuable in mobile applications, such as wearable AC systems, and it enables, for example, more comfortable user experience, lighter and more compact systems, longer battery life per charge, and wider range of operation.

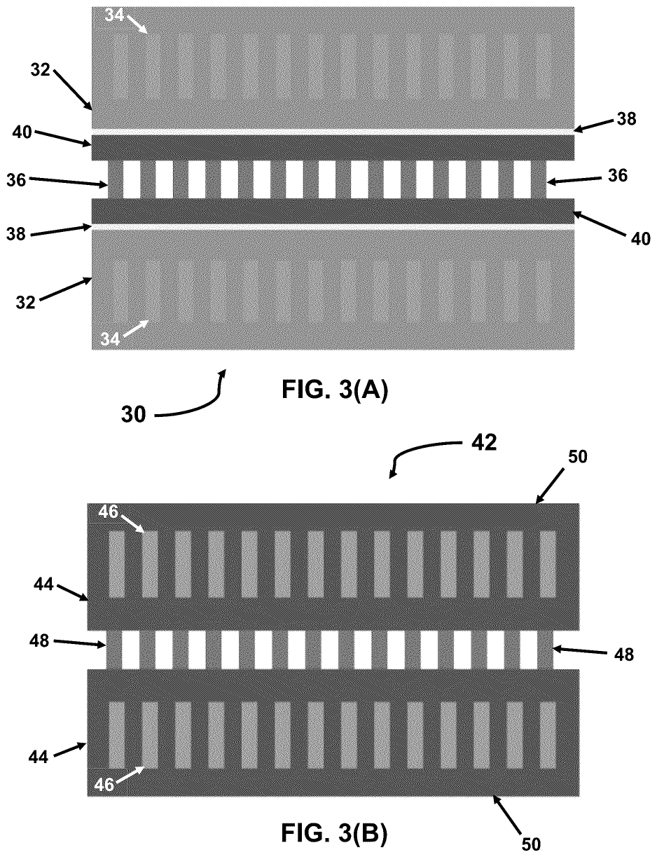

FIG. 3(A) schematically represents another exemplary embodiment of a conventional TEC (Thermoelectric Cooler) module, while FIG. 3(B) schematically represents another exemplary embodiment of a TEC (Thermoelectric Cooler) module provided in accordance with presently disclosed subject matter.

Per FIG. 3(A), conventional TEC module 30 is provided with contact plates 32 which each have a respective plurality of enclosed fluid passages 34. As with FIG. 1(A), fluid passages 34 generally allow for thermal management, to improve heat transfer to contribute to a stable temperature differential across the plurality of respective thermoelectric (TE) elements 36. As shown, module 30 is composed of alternating p-type and n-type thermoelectric elements 36, which are arranged in a structured manner between the two ceramic substrates 32. To complete the overall structure of the exemplary embodiment of representative conventional module 30, a pair of layers of thermal interface material 38 appear respectively sandwiched between substrates 32 and a pair of ceramic plates 40, as shown in FIG. 1(A).

FIG. 3(B) schematically represents a TEC (Thermoelectric Cooler) module generally 42 provided in accordance with presently disclosed subject matter. As shown, such module 42 provides an enhanced thermal performance TEC configuration in accordance with the presently disclosed subject matter, with reduced thermal resistance layers. In particular, for example, the pair of layers of thermal interface material 38 and pair of ceramic plates 40 of FIG. 3(A) are entirely omitted, so that a pair of TE ceramic contact plates 44, with a respective plurality of fluid passages 46, directly capture the plurality of TE elements 48. Thus, the respective pair of TE ceramic contact plates 44 each have built-in enclosed fluid passages 46, while a respective pair of ceramic plates 50 otherwise cap the micro-passages, as illustrated.

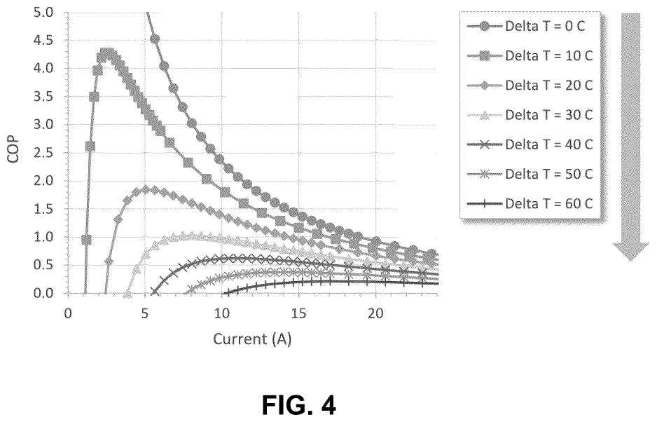

FIG. 4 graphically illustrates a dropping maximum Coefficient of Performance (COP) as temperature difference between hot and cold side of the thermoelectric module increases, per data as available at www.europeanthermodynamics.com. Coefficient of Performance (COP) (or Efficiency), is the heat absorbed at the cold side Q_{c} divided by the input power Pₑₗ of the Peltier element: COP=Q_{c}/Pₑₗ. The COP is in principal the efficiency of the Peltier element when cooling.

As outlined above, conventional or known thermoelectric modules comprise thermoelectric elements (or legs) sandwiched between two electrically insulating ceramic plates. Depending on the direction of the electric current, thermal energy flows from one end to another (that is, from one ceramic plate to the other). The plate at the relatively lower temperature is called the cold plate and the plate at the relatively higher temperature is called the hot plate. The thermoelectric module, including the ceramic plates, is sandwiched between two additional plates with built-in heat dissipation structure which are either air-cooled or liquid-cooled (single-phase or multiphase). On the backside of each plate, built-in fluid passages enable the fluid flow to provide heat transfer capacity on each side. The extra plates in contact with each ceramic plate add additional resistance to the heat transfer path from the thermoelectric elements to ambient (that is, to a heat sink).

The efficiency of a thermoelectric system, when used in cooling mode, is strongly affected by the temperature difference between its hot and cold sides as is shown in FIG. 4. This temperature difference, in part, is a function of the power input to the system and the heat transfer resistance on both cold and hot sides of the thermoelectric module. Significant gains in power performance and energy efficiency are achieved by reducing the total thermal resistance and consequently the temperature difference between the hot and cold side of the TEC module. The presently disclosed subject matter achieves such reduction through eliminating the additional layers sandwiching the ceramic layers and integrating the fluidic grooves into the ceramic directly, as represented by FIG. 1(B), 2(B), and 3(B) herewith. The improved heat transfer capability then allows for a denser distribution of thermoelectric elements (FIG. 2(B)) in the module, which further improve the performance of the module, and the system that wraps around the module.

This written description uses examples to disclose the presently disclosed subject matter, including the best mode, and also to enable any person skilled in the art to practice the presently disclosed subject matter, including making and using any devices or systems and performing any incorporated methods. The patentable scope of the presently disclosed subject matter is defined by the claims, and may include other examples that occur to those skilled in the art. Such other examples are intended to be within the scope of the claims if they include structural and/or step elements that do not differ from the literal language of the claims, or if they include equivalent structural and/or elements with insubstantial differences from the literal languages of the claims. In any event, while certain embodiments of the disclosed subject matter have been described using specific terms, such description is for illustrative purposes only, and it is to be understood that changes and variations may be made without departing from the spirit or scope of the subject matter. Also, for purposes of the present disclosure, the terms “a” or “an” entity or object refers to one or more of such entity or object. Accordingly, the terms “a”, “an”, “one or more,” and “at least one” can be used interchangeably herein.

1. A thermoelectric module for transferring heat from one side to the other, using Peltier effect, to provide for both cooling and heating, comprising:
a pair of ceramic plates, with each plate forming a respective plurality of fluid passages integrated directly into a respective outward facing surface of said ceramic plates, and with said plates formed in opposing parallel positions; and
a plurality of thermoelectric (TE) elements directly captured between said pair of ceramic plates without intervening layers of thermal interface material and without intermediate ceramic plates.

2. The thermoelectric module according to claim 1, wherein:
said ceramic plates respectively enclose said fluid passages; and
said module further comprises an additional pair of ceramic plates situated to cap the locations of the fluid passages.

3. The thermoelectric module according to claim 1, wherein:
said thermoelectric module comprises a thermoelectric cooler module;
said ceramic plates comprise dielectric material contact substrates; and
said plurality of thermoelectric (TE) elements comprise alternating p-type and n-type thermoelectric elements, arranged in a structured manner between the two contact substrates.

4. The thermoelectric module according to claim 3, wherein said thermoelectric elements are arranged in parallel between the two contact substrates.

5. The thermoelectric module according to claim 1, wherein said fluid passages comprise at least one of custom-patterned grooves, pins, and other geometries.

6. (canceled)

7. A thermoelectric cooler (TEC) module for transferring heat from one side to the other, using Peltier effect, to controllably create temperature difference between two sides of the module, comprising:
a pair of dielectric material contact substrates, with said contact substrates formed in opposing parallel positions, and with each contact substrate having a respectively outward facing surface;
a respective plurality of fluid passages formed directly in each of said outward facing surfaces, and comprising at least one of custom-patterned grooves, pins, and other geometries integrated into said outward facing surfaces; and
a plurality of thermoelectric (TE) legs, arranged in parallel, and directly captured between said pair of contact substrates without intervening layers of thermal interface material and without intermediate ceramic plates.

8. (canceled)

9. The thermoelectric cooler (TEC) module according to claim 7, wherein said module further comprises an additional pair of ceramic plates situated to cap the locations of the fluid passages.

10. The thermoelectric cooler (TEC) module according to claim 7, wherein said plurality of thermoelectric (TE) legs comprise alternating p-type and n-type thermoelectric elements, arranged in a structured manner between the two contact substrates.

11. Methodology for providing an improved thermoelectric module for transferring heat from one side to the other, using Peltier effect, to provide for both cooling and heating, comprising:
providing a pair of ceramic plates, configured in opposing parallel positions with each plate forming a respective outward facing surface; forming a plurality of fluid passages directly in each respective outward facing surface of said ceramic plates by removing solid material from the ceramic plates; and
providing a plurality of thermoelectric (TE) elements directly captured between said pair of ceramic plates, to configure the TE elements for being relatively closer to the plurality of fluid passages, whereby the module has reduced thermal resistance for enhanced performance.

12. The methodology according to claim 11, further comprising providing an additional pair of ceramic plates situated to cap the locations of the fluid passages, to respectively enclose said fluid passages.

13. The methodology according to claim 11, wherein:
said thermoelectric module comprises a thermoelectric cooler module;
said ceramic plates comprise dielectric material contact substrates; and
said plurality of thermoelectric (TE) elements comprise alternating p-type and n-type thermoelectric elements, arranged in a structured manner between the two contact substrates.

14. The methodology according to claim 13, wherein said thermoelectric elements are arranged in parallel between the two contact substrates.

15. The methodology according to claim 11, wherein said fluid passages comprise at least one of custom-patterned grooves, pins, and other geometries integrated into the respective outward facing surfaces of said ceramic plates.

16. The methodology according to claim 11, wherein said plurality of thermoelectric elements are arranged between the pair of ceramic plates without intervening layers of thermal interface material.

17. The methodology according to claim 12, wherein providing the additional pair of ceramic plates comprises forming said additional pair of ceramic plates from the same ceramic material as the pair of ceramic plates, to reduce thermal stress and tension.
